(19) United States
(12) Patent Application Publication
(10) Pub. No.: US 2026/0247895 A1
(43) Pub. Date: Aug. 20, 2026

(54) METHOD FOR PACKAGING RADIO FREQUENCY IDENTIFICATION (RFID) CHIP

(71) Applicant: Sichuan Kiloway Technologies Co., Ltd., Mianyang (CN)

(72) Inventors: Junhua Mao, Mianyang (CN); Yi Liu, Mianyang (CN)

(21) Appl. No.: 19/543,801

(22) Filed: Feb. 18, 2026

(30) Foreign Application Priority Data
Feb. 19, 2025 (CN) 202510179604.5

(51) Int. Cl. H10P 58/00; H10P 54/20; H10W 99/00

(52) U.S. Cl. CPC H10P 58/20; H10P 54/20; H10W 99/00

(57) ABSTRACT

A method for packaging radio frequency identification (RFID) chips is provided. The method includes: coating a conductive medium onto surfaces of the RFID chips of a whole wafer; and then performing film expansion to create gaps between adjacent RFID chips, to obtain an assembly of spaced-apart chips; attaching a conductor layer to a surface of the conductive medium of the assembly of the spaced-apart chips, and performing hot pressing to cure the conductive medium, to bond the RFID chips to the conductor layer; severing the conductor layer between two pads of each of the RFID chips, and then dicing the conductor layer along the gaps between the adjacent RFID chips to form independent modified RFID chips; and performing the packaging by using two portions of the conductor layer in each of the modified RFID chips as bonding points.

### CROSS REFERENCE TO RELATED APPLICATION

This patent application claims the benefit and priority of Chinese Patent Application No. 202510179604.5 filed with the China National Intellectual Property Administration on Feb. 19, 2025, the disclosure of which is incorporated by reference herein in its entirety as part of the present application.

### TECHNICAL FIELD

The present disclosure relates to the technical field of chip packaging, and in particular to a method for packaging radio frequency identification (RFID) chips.

### BACKGROUND

A radio frequency identification (RFID, commonly known as electronic tag) chip typically requires only two pads (i.e., bonding points), namely RF⁺ and RF⁻ (as shown in FIG. 1). In a conventional packaging process, chips are individually picked up by a nozzle and precisely placed onto unbonded antenna pads through vision-based positioning (as shown in FIG. 2). In new direct die attach (DDA) technology, an ejector pin is used to directly push a die upward from a back side of a blue tape, allowing the die to protrude and release from the blue tape and simultaneously bond to an antenna. Although this improves the efficiency, it is still a chip-by-chip process and still requires high positioning accuracy.

With the continuous advancement of RFID chip technology, chip sizes become smaller and smaller. Currently, the smallest chip size in the industry has reached approximately 0.26 mm×0.26 mm, which places higher demands on the positioning accuracy of packaging and also causes a price of related equipment to continue to rise.

Existing packaging equipment, whether using a pick-up head method or a DDA method, are generally dependent on a sequential pipeline operation mode in which the dies are picked up and packaged one at a time. With the current single-wafer capacity reaching 600,000 dies to 800,000 dies, this approach presents a significant challenge in terms of a packaging speed. Even the fastest packaging machine in the industry has a theoretical speed of only 100 k/hour, and still takes about 6 hours to complete packaging of a single wafer.

While the manufacturing cost per chip is reduced due to reduction of the chip size under ongoing progress based on Moore's law, this is accompanied by higher-cost packaging equipment and a higher-precision antenna fabrication process, which to some extent offsets savings in the manufacturing cost of the chip. Given the demand for tags in the logistics industry of an order of hundreds of billions, an existing packaging speed is clearly insufficient to meet requirements of practical applications.

### SUMMARY

In view of this, the present disclosure is intended to provide a method for packaging radio frequency identification (RFID) chips. The method provided by the present disclosure eliminates reliance on high-precision equipment, eliminates the need to increase a procurement cost and a depreciation cost of equipment and a consumable cost, and also significantly improves a packaging speed and a labor efficiency.

To achieve the above object, the present disclosure provides the following technical solutions.

The present disclosure provides a method for packaging RFID chips, including the following steps:
coating a conductive medium onto surfaces of the RFID chips of a whole wafer having a transfer film, with the RFID chips being arranged in close contact; and then performing film expansion to create gaps between adjacent RFID chips, to obtain an assembly of spaced-apart chips;
attaching a conductor layer to a surface of the conductive medium of the assembly of the spaced-apart chips, and performing hot pressing to cure the conductive medium, to bond the RFID chips to the conductor layer;
severing the conductor layer between two pads of each of the RFID chips, and then dicing the conductor layer along the gaps between the adjacent RFID chips to form independent modified RFID chips, where each of the modified RFID chips is provided with two portions of the conductor layer; and
performing the packaging by using the two portions of the conductor layer in each of the modified RFID chips as bonding points.

In some embodiments, the gaps between the adjacent RFID chips in the assembly of the spaced-apart chips each have a spacing of 50-100 μm.

In some embodiments, the conductive medium includes one selected from the group consisting of a solder paste, and an anisotropic conductive adhesive.

In some embodiments, the RFID chips each have a size of (100-300) μm×(100-300) μm.

In some embodiments, the conductor layer has a thickness of 50-80 μm.

In some embodiments, the conductor layer includes one selected from the group consisting of a metal foil, and a multilayer composite conductive material.

In some embodiments, the severing the conductor layer between the two pads of each of the RFID chips is conducted by laser cutting or etching.

In some embodiments, the dicing the conductor layer along the gaps between the adjacent RFID chips is conducted by: dicing the conductor layer along fixed horizontal and vertical paths or along centerlines of the gaps between the adjacent RFID chips.

In some embodiments, a coating thickness of the conductive medium is in a range of 10-50 μm.

The present disclosure provides a method for packaging RFID chips, in which a conductor layer is provided on pads of the RFID chips, and obtained modified RFID chips are packaged, making a package size of each of the RFID chips larger than a physical size of each of the RFID chips, that is, transforming ultra-small RFID chips into conventional-size RFID chips or even larger RFID chips. This reduces the difficulty of the packaging, eliminates reliance on expensive high-precision equipment, and eliminates the need to increase a procurement cost and a depreciation cost of an equipment and a consumable cost.

Currently, in the RFID chip industry, chip-by-chip packaging is used. During the chip-by-chip packaging, as RFID chip sizes become smaller and smaller, precision requirements for die picking become increasingly higher, resulting in low packaging efficiency. In the present disclosure, transformation of ultra-small chips into conventional-size chips or even larger chips significantly improves a packaging speed, and compared with the existing sequential pipeline operation mode, greatly shortens a wafer packaging time and could better meet the massive need for tags.

By an innovative packaging method of the present disclosure, conventional RFID packaging equipment and even laminators could be used for ultra-small chip packaging, providing strong support for the large-scale application in the RFID industry.

The present disclosure reduces the difficulty of packaging operations and improves a production efficiency.

### BRIEF DESCRIPTION OF THE DRAWINGS

FIG. 1 shows a schematic structural diagram of an RFID chip;

FIG. 2 shows a schematic diagram showing an RFID chip being placed on an unbonded antenna pad;

FIGS. 3A-3B show schematic structural diagrams of a whole wafer having a transfer film, with chips being arranged in close contact of an embodiment of the present disclosure, in which FIG. 3A shows a schematic top view, and FIG. 3B shows a schematic cross-sectional view taken along a diameter of a wafer;

FIGS. 4A-4B show schematic structural diagrams of an assembly of spaced-apart chips an embodiment of the present disclosure, in which FIG. 4A shows a schematic top view, and FIG. 4B shows a schematic cross-sectional view taken along the diameter of the wafer;

FIGS. 5A-5B shows schematic diagrams showing a conductor layer being attached to a surface of a conductive medium of the assembly of the spaced-apart chips of an embodiment of the present disclosure, in which FIG. 5A shows a schematic top view, and FIG. 5B shows a schematic cross-sectional view taken along the diameter of the wafer;

FIGS. 6A-6B shows schematic diagrams showing severing the conductor layer between two pads of each of the RFID chips of an embodiment of the present disclosure, in which FIG. 6A shows a schematic top view, and FIG. 6B shows a schematic cross-sectional view after the severing;

FIGS. 7A-7B show schematic diagrams after dicing the conductor layer along gaps between adjacent RFID chips of an embodiment of the present disclosure, in which FIG. 7A shows a schematic top view, and FIG. 7B shows a schematic cross-sectional view;

FIG. 8 shows a schematic diagram showing dicing the conductor layer along fixed horizontal and vertical paths of an embodiment of the present disclosure;

FIG. 9 shows a schematic diagram showing dicing of the conductor layer along centerlines of the gaps between the adjacent RFID chips of an embodiment of the present disclosure; and

FIGS. 10A-10B show schematic diagrams of a packaged modified RFID chip of an embodiment of the present disclosure, in which FIG. 10A shows a schematic top view, and FIG. 10B shows a schematic cross-sectional view.

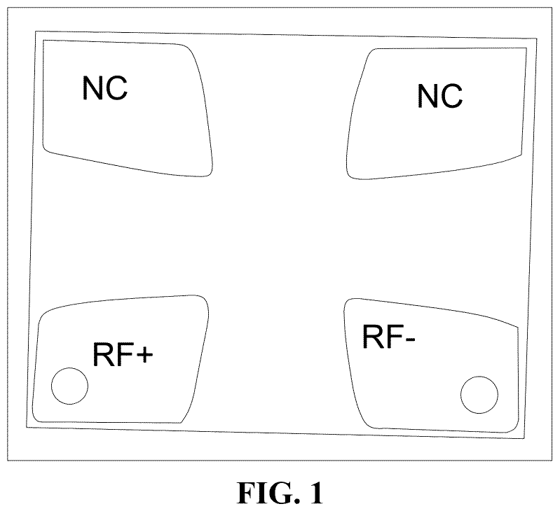

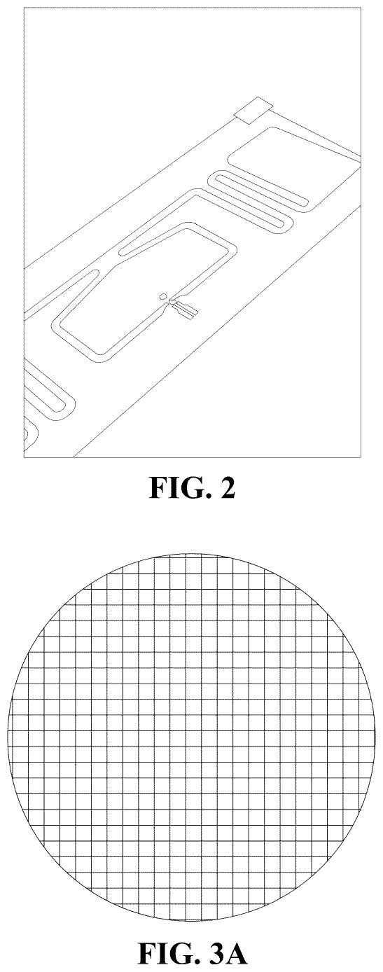

### DETAILED DESCRIPTION OF THE EMBODIMENTS

The present disclosure provides a method for packaging RFID chips, including the following steps:
coating a conductive medium onto surfaces of the RFID chips of a whole wafer having transfer film, with the RFID chips being arranged in close contact; and then performing film expansion to create gaps between adjacent RFID chips, to obtain an assembly of spaced-apart chips;
attaching a conductor layer to a surface of the conductive medium of the assembly of the spaced-apart chips, and performing hot pressing to cure the conductive medium, to bond the RFID chips to the conductor layer;
severing the conductor layer between two pads of each of the RFID chips, and then dicing the conductor layer along the gaps between the adjacent RFID chips to form independent modified RFID chips, where each of the modified RFID chips is provided with two portions of the conductor layer; and
performing the packaging by using the two portions of the conductor layer in each of the modified RFID chips as bonding points.

In the present disclosure, a conductive medium is coated onto surfaces of RFID chips of a whole wafer having a transfer film, and the RFID chips are arranged in close contact; and film expansion is then performed to create gaps between adjacent RFID chips to obtain an assembly of spaced-apart chips.

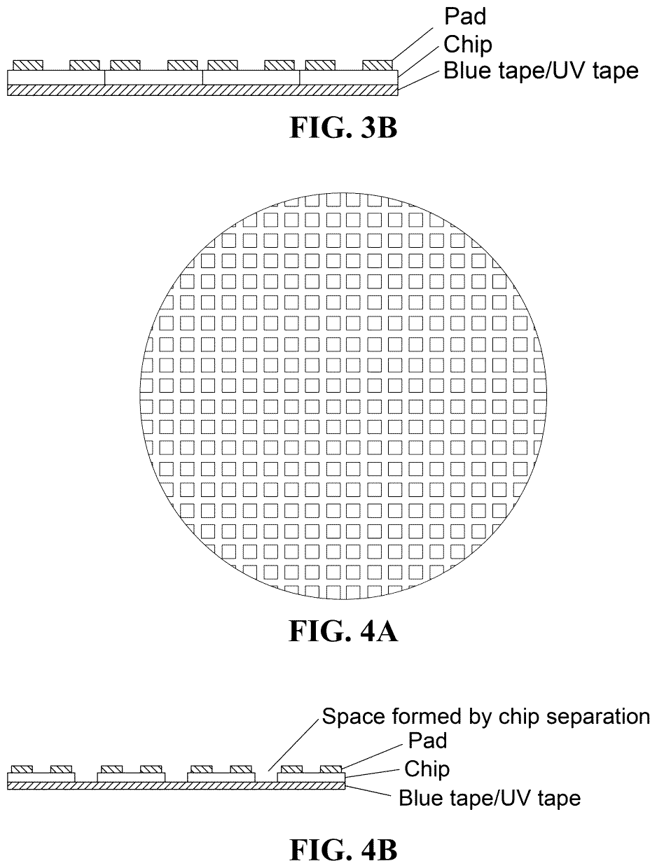

In the present disclosure, schematic structural diagrams of a whole wafer with a transfer film and having chips arranged in close contact are shown in FIGS. 3A-3B. The RFID chips are arranged in a tight and ordered array in the whole wafer. In some embodiments of the present disclosure, the transfer film is one selected from the group consisting of a blue tape, and a UV tape.

In the present disclosure, there are no special requirements for the RFID chips, and any RFID chips well known in the art may be adopted. In the present disclosure, each of the RFID chips have two pads, and is connected to an unbonded antenna via the pads. In some embodiments of the present disclosure, the RFID chips each have a size of (100-300) μm×(100-300) μm, and in specific embodiments, the RFID chips each have the size of 100 μm×100 μm, 150 μm×150 μm, 200 μm×200 μm, 260 μm×260 μm, or 300 μm×300 μm.

In some embodiments of the present disclosure, the conductive medium includes one selected from the group consisting of a solder paste, and an anisotropic conductive adhesive. In the present disclosure, use of the anisotropic conductive adhesive ensures that the conductive medium is conductive in a vertical direction but non-conductive in a lateral direction. In some embodiments of the present disclosure, a coating thickness of the conductive medium is in a range of 10-50 μm, and in specific embodiments, the coating thickness of the conductive medium is 10 μm, 20 μm, 30 μm, 40 μm, or 50 μm. In the present disclosure, a coating area of the conductive medium is sufficient to cover all RFID chips.

In the present disclosure, there are no special requirements for the specific implementation of the film expansion, and film expansion methods well known in the art may be adopted. After the film expansion, gaps are created between the RFID chips that are originally tightly packed, as shown in FIGS. 4A-4B. In some embodiments of the present disclosure, the gaps between the adjacent RFID chips in the assembly of the spaced-apart chips each have a spacing of 50-100 μm, and in specific embodiments, the spacing is 50 μm, 60 μm, 70 μm, 80 μm, 90 μm, or 100 μm.

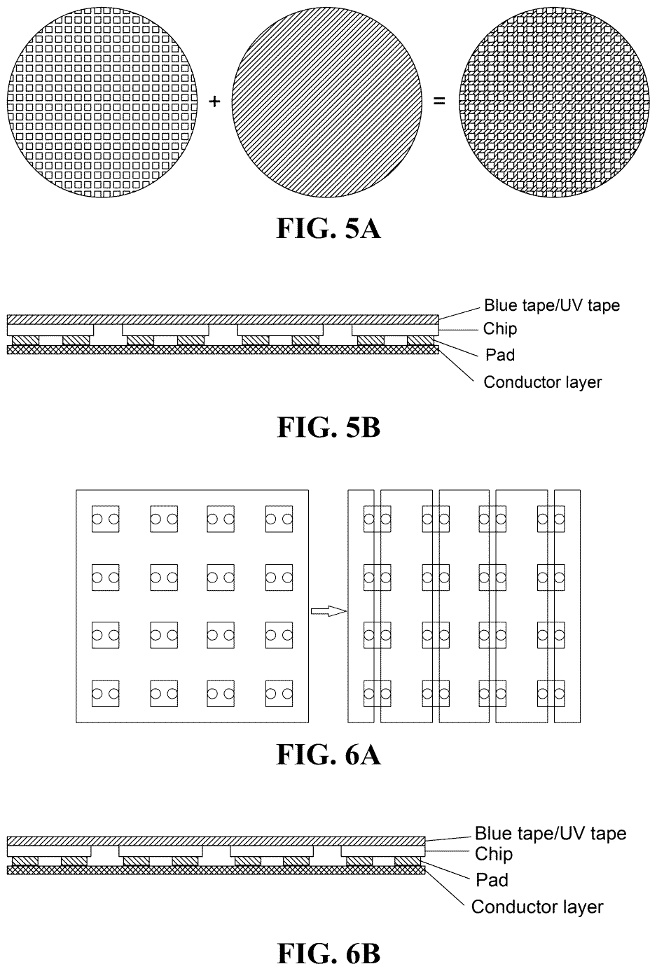

In the present disclosure, after obtaining the assembly of the spaced-apart chips, as shown in FIGS. 5A-5B, a conductor layer is attached to a surface of the conductive medium of the assembly of the spaced-apart chips, and hot pressing is performed to cure the conductive medium to bond the RFID chips to the conductor layer.

In some embodiments of the present disclosure, the conductor layer includes one selected from the group consisting of a metal foil, and a multilayer composite conductive material. In the present disclosure, there is no special limitation on a specific composition of the conductor layer, and any material capable of achieving conductivity may be adopted. In an embodiment of the present disclosure, specifically an Al film on a polyterephthalate plastic (PET) carrier is adopted. In some embodiments of the present disclosure, the conductor layer has a thickness of 50-80 μm, and in specific embodiments, the conductor layer has the thickness of 50 μm, 60 μm, 70 μm, or 80 μm. In the present disclosure, by controlling the thickness of the conductor layer within the aforementioned range, a firm bond between each of the RFID chips and the unbonded antenna could be achieved.

In some embodiments of the present disclosure, an area of the conductor layer is greater than or equal to an area of the transfer film after the film expansion. Since there may be poor alignment of chips caused by an unsatisfactory film expansion effect, in the present disclosure a whole large-area conductor layer is used to allow all RFID chips to attach to the conductor layer without requiring precision alignment, followed by severing and dicing of the conductor layer using machine vision according to individual chip deviations, thereby improving an packaging efficiency.

In the present disclosure, there are no special limitations on conditions of the hot pressing, as long as the conductive medium could be cured to achieve a firm bond between the RFID chips and the conductor layer. In the art, general hot pressing conditions include: a hot pressing temperature of 160-190° C., a pressure of 1-2 N, and a duration of 6-10 seconds.

In some embodiments of the present disclosure, after the RFID chips are bonded to the conductor layer, the conductor layer between the two pads of each of the RFID chips is severed (as shown in FIGS. 6A-6B).

In some embodiments of the present disclosure, severing the conductor layer between the two pads of each of the RFID chips is conducted by laser cutting or etching. In the present disclosure, a purpose of the severing the conductor layer between the two pads of each of the RFID chips is to remove short circuits. In the present disclosure, there are no special requirements for specific implementation conditions of the laser cutting and the etching, as long as only the conductor layer is severed without damaging the RFID chips. For example, the etching could achieve the purpose of the severing the conductor layer between the two pads of each of the RFID chips by coating with a photoresist or a photosensitive ink and performing optical scanning exposure. In the present disclosure, the etching has a lower cost and a higher precision.

In some embodiments of the present disclosure, during the severing, the conductor layer between the two pads of each of the RFID chips is severed using the machine vision and/or laser according to the individual chip deviations. Since such arrangement generally has regular errors with a relatively small difference, the laser cutting substantially follows a relatively straight path, and achieves a higher cutting efficiency than a completely random arrangement.

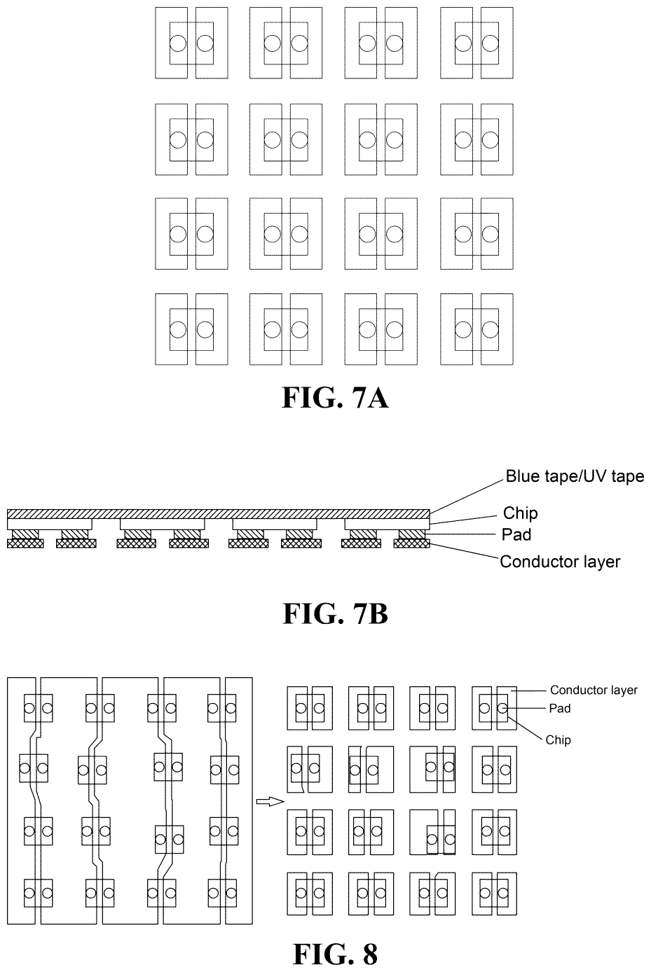

In the present disclosure, after the conductor layer between the two pads of each of the RFID chips is severed, the conductor layer is then diced along the gaps between adjacent RFID chips to form independent modified RFID chips, each of the modified RFID chips is provided with two portions of the conductor layer (as shown in FIGS. 7A-7B).

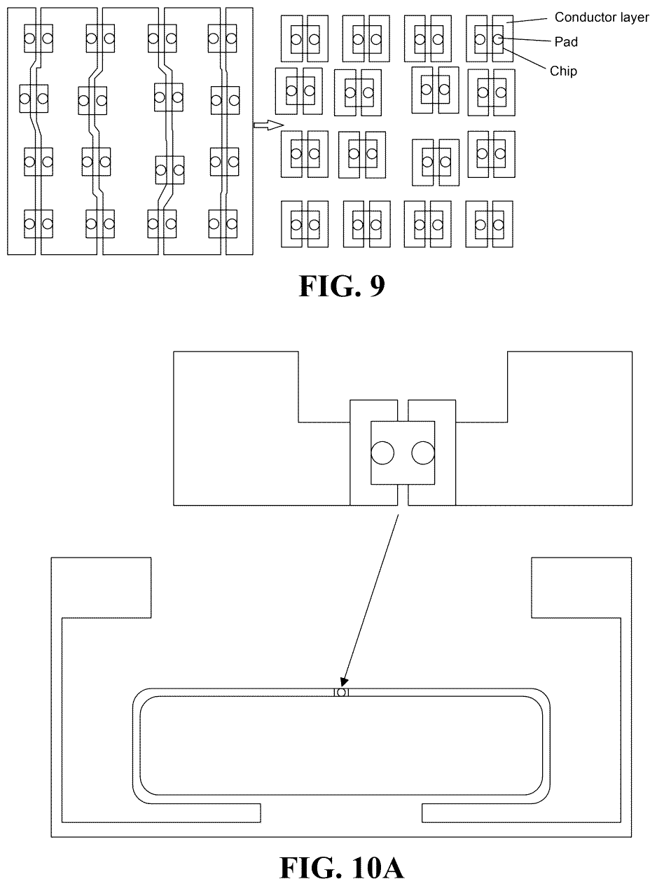

In some embodiments of the present disclosure, the conductor layer is diced along fixed horizontal and vertical paths or along centerlines of the gaps between the adjacent RFID chips. In the present disclosure, a process of the dicing is the same as a process of the severing described above, which is not repeated here. In the present disclosure, during the dicing along the fixed horizontal and vertical paths, since chip positions have relatively small deviations, use of the fixed horizontal and vertical paths will not affect severing paths (as shown in FIG. 8). When the conductor layer is diced along the centerlines of the gaps between the adjacent RFID chips, better results could be achieved by taking into account correction of individual chip offsets (as shown in FIG. 9).

In the present disclosure, a size of each of the modified RFID chips is larger than a size of each of the RFID chips. As a preferred solution, the size of each of the modified RFID chips is 50 μm to 100 μm larger than the size of each of the RFID chips, that is, a side length of each of the modified RFID chips is 50 μm to 100 μm longer than a side length of each of the RFID chips. In a specific embodiment, the size of each of the modified RFID chips is 50 μm, 60 μm, 70 μm, 80 μm, 90 μm or 100 μm larger than the size of each of the RFID chips.

In the present disclosure, the modified RFID chips are still attached to a flexible transfer film, and are packaged directly or subsequent to a tape-and-reel process.

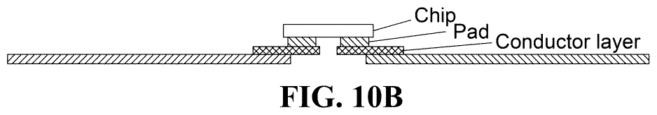

In the present disclosure, during packaging, the two portions of the conductor layer in each of the modified RFID chips are used as bonding points for the packaging (as shown in FIGS. 10A-10B).

In the present disclosure, since the size of each of the modified RFID chips is larger than size of an original RFID chip, conventional RFID packaging may be adopted, without need to purchase an expensive high-precision packaging equipment, and when the size of each of the modified RFID chips is large enough, it may even be possible to perform the packaging using only a laminator.

A method for packaging modified RFID chips and RFID chips provided by the present disclosure will be described in detail with reference to examples below, which should not be construed as limiting the scope of the present disclosure.

### Example 1

A method for packaging RFID chips was performed by the following steps.

A conductive medium (a solder paste) (with a coating thickness of 19 μm) was coated onto surfaces of the RFID chips (300 μm×300 μm) of a whole wafer having a blue tape, where the RFID chips were arranged in close contact, and then film expansion was performed to create gaps between adjacent RFID chips (with a spacing of the gaps between adjacent chips of 60-70 μm), to obtain an assembly of spaced-apart chips.

A conductor layer (specifically, an Al film on a PET carrier, with a thickness of 50 μm) was attached to a surface of the conductive medium of the assembly of the spaced-apart chips, with an Al film side being in contact with the conductive medium, and a resulting system was subjected to hot pressing at 185° C. on both upper and lower sides for 8 seconds and under a pressure of 1.2 N to cure the conductive medium to bond the RFID chips to the conductor layer;

The conductor layer between two pads of each of the RFID chips was severed by means of laser cutting, and then the conductor layer along centerlines of the gaps between adjacent RFID chips to form independent modified RFID chips, where each of the modified RFID chips was provided with two portions of the conductor layer.

Packaging was performed by using the two portions of the conductor layer in each of the modified RFID chips as bonding points, using Muehlbauer DDA packaging equipment, which greatly improved the packaging efficiency.

The above descriptions are merely preferred embodiments of the present disclosure. It should be noted that a person of ordinary skill in the art may further make several improvements and modifications without departing from the principle of the present disclosure, but such improvements and modifications should be considered as falling within the scope of the present disclosure.

What is claimed is:

1. A method for packaging radio frequency identification (RFID) chips, comprising the following steps:
coating a conductive medium onto surfaces of the RFID chips of a whole wafer having a transfer film, with the RFID chips being arranged in close contact; and then performing film expansion to create gaps between adjacent RFID chips, to obtain an assembly of spaced-apart chips, wherein the conductive medium is an anisotropic conductive adhesive, and the anisotropic conductive adhesive ensures that the conductive medium is conductive in a vertical direction but non-conductive in a lateral direction;
attaching a conductor layer to a surface of the conductive medium of the assembly of the spaced-apart chips, and performing hot pressing to cure the conductive medium, to bond the RFID chips to the conductor layer, an area of the conductor layer being greater than or equal to an area of the transfer film after the film expansion;
severing the conductor layer between two pads of each of the RFID chips using machine vision, and then dicing the conductor layer along the gaps between the adjacent RFID chips using the machine vision to form independent modified RFID chips, wherein each of the modified RFID chips is provided with two portions of the conductor layer; and
performing the packaging by using the two portions of the conductor layer in each of the modified RFID chips as bonding points, wherein the packaging is for connection to an unbonded antenna;
wherein the gaps between the adjacent RFID chips in the assembly of the spaced-apart chips each have a spacing of 50-100 μm;
the conductor layer has a thickness of 50-80 μm; and
the dicing the conductor layer along the gaps between the adjacent RFID chips is conducted by: dicing the conductor layer along fixed horizontal and vertical paths.

2. The method of claim 1, wherein the RFID chips each have a size of (100-300) μm×(100-300) μm.

3. The method of claim 1, wherein the conductor layer comprises one selected from the group consisting of a metal foil, and a multilayer composite conductive material.

4. The method of claim 1, wherein the severing the conductor layer between the two pads of each of the RFID chips is conducted by laser cutting or etching.
